(19) United States
(12) Patent Application Publication
(10) Pub. No.: US 2017/0338447 A1
(43) Pub. Date: Nov. 23, 2017

(54) CHARGE CONNECTION LAYER, METHOD FOR MANUFACTURING THE SAME, AND LAMINATED OLED COMPONENT

(71) Applicant: Shenzhen China Star Optoelectronics Technology Co. Ltd., Shenzhen (CN)

(72) Inventor: Chao XU, Shenzhen (CN)

(21) Appl. No.: 14/897,689

(22) PCT Filed: Aug. 27, 2015
(86) PCT No.: PCT/CN2015/088206

§ 371 Date: Dec. 11, 2015

(30) Foreign Application Priority Data
Jun. 30, 2015 (CN) 201510372259.3

(51) Int. Cl. H01L 51/56; H01L 51/50; H01L 51/00; H01L 51/52

(52) U.S. Cl. CPC H01L 51/56; H01L 51/5221; H01L 51/5206; H01L 51/508; H01L 51/0032; H01L 51/5012; H01L 51/5008; H01L 51/506

(57) ABSTRACT

Disclosed is a charge connection layer, a method for manufacturing the same, and a laminated OLED component. The charge connection layer includes a first material layer and a second material layer which are both provided therein with protrudes and recessions. Each protrude of the first material layer extends into a corresponding recession of the second material layer. Each protrude of the second material layer extends into a corresponding recession of the first material layer. The charge connection layer is able to generate more carriers, whereby the performance of the charge connection layer can be improved, and the efficiency and lifespan of the laminated OLED component can be prolonged and improved.

### CROSS-REFERENCE TO RELATED APPLICATIONS

The present application claims the priority of Chinese patent application CN201510372259.3, entitled “Charge connection layer, method for manufacturing the same, and laminated OLED component” and filed on Jun. 30, 2015, the entirety of which is incorporated herein by reference.

### TECHNICAL FIELD

The present disclosure relates to the technical field of image display, and in particular, to an electric-charge connection layer, a method for manufacturing the same, and a laminated OLED component.

### TECHNICAL BACKGROUND

In the technical field of display, organic light-emitting diode (OLED) display devices have been considered as one of the best illumination and display devices in the 21^{st} century for their advantages such as low cost, low power consumption, quick response speed, wide viewing angle, high contrast ratio, high brightness, flexibility, etc. At present, low luminous efficiency and short working life of OLED components have become the main factors that hinder the industrial development of OLEDs.

In order to improve the luminous efficiency of an OLED component, a traditional OLED component has been gradually replaced by a laminated OLED component. By laminating light-emitting units in the laminated OLED component, brightness and luminous efficiency thereof are effectively improved, and a high brightness in the presence of a low current density is also achieved, which prevents occurrence of leakage current and breakdown of an electric field, and thus prolongs the lifespan of the OLED component.

In the laminated OLED component, a number of light-emitting units are connected in serials through electric-charge connection layers (also referred to as charge generation layers, CGL), so that all the light-emitting units can be driven under a same current density, thereby improving the brightness of the laminated OLED component considerably. The charge connection layer is a critical part of a laminated OLED component, because it provides both electrons and holes for neighboring light-emitting units. Hence, performance of the charge connection layer has a direct influence on performance of the OLED component.

Therefore, it is of great importance to improve the performance of charge connection layer as it is directly related to product competition of the OLED display device.

### SUMMARY OF THE INVENTION

The objective of the present disclosure is to improve the performance of an electric-charge connection layer. To achieve this objective, the present disclosure first provides a charge connection layer which comprises a first material layer and a second material layer, the first material layer and the second material layer both having protrudes and recessions. Each protrude of the first material layer extends into a corresponding recession of the second material layer, and each protrude of the second material layer extends into a corresponding recession of the first material layer.

In one embodiment of the present disclosure, the first material layer and the second material layer form comb-like structures which are fitted together.

In one embodiment of the present disclosure, the first material layer is a P-type material layer, and the second material layer is an N-type material layer. Alternatively, the first material layer is an N-type material layer, and the second material layer is P-type material layer.

In one embodiment of the present disclosure, P-type dopant in the P-type material layer is selected from any one or combinations of the following: HAT-CN, FeCl₃:NPB, MoO₃:NPB, and F₄-TCNQ:m-MTDATA.

In one embodiment of the present disclosure, N-type dopant in the N-type material layer is selected from any one or combinations of the following: Li, Mg, Ca, Cs, LiF, CsF, Cs₂CO₃, CsN₃, and Rb₂CO₃.

In one embodiment of the present disclosure, the protrudes and the recessions of the first material layer are formed on a first side of the first material layer, and a second side of the first material layer is flat.

In one embodiment of the present disclosure, the protrudes and the recessions of the second material layer are formed on a second side of the second material layer, and a first side of the second material layer is flat.

The present disclosure further provides a laminated OLED component which comprises a first light-emitting unit, a second light-emitting unit, and one of the charge connection layers as mentioned above. The first light-emitting unit and the 20 second light-emitting unit are connected in serials through the charge connection layer.

The present disclosure further provides a method for manufacturing a charge connection layer. The method comprises steps of: forming a first material unit from a first material, and forming a plurality of protrudes and a plurality of recessions on the first material unit using the first material; and filling each of the recessions with a second material, and forming a second material unit over the protrudes and the filled recessions using the second material.

In one embodiment of the present disclosure, the first material is a P-type material and the second material is an N-type material. Alternatively, the first material is an N-type material and the second material is a P-type material.

For charge connection layers with a same appearance and size, the area of a contact region of P/N-type structures (i.e., the area of a contact region of the first material layer and the second material layer) in the charge connection layer provided by the present disclosure is considerably larger than that of a contact region of P/N-type structures in an existing charge connection layer. Therefore, compared with an existing charge connection layer, the charge connection layer provided by the present disclosure is able to generate more carriers, whereby the performance of the charge connection layer can be improved, and the efficiency and lifespan of the entire laminated OLED component can be improved and prolonged.

Other features and advantages of the present disclosure will be further explained in the following description, and will partly become self-evident therefrom, or be understood through the implementation of the present disclosure. The objectives and advantages of the present disclosure will be achieved through the structures specifically pointed out in the description, claims, and the accompanying drawings.

### BRIEF DESCRIPTION OF THE DRAWINGS

For further illustrating the technical solutions provided in the embodiments of the present disclosure as well as in the prior art, brief introductions will be given below to the accompanying drawings involved in the embodiments and the prior an.

FIG. 1 schematically shows a structure of a laminated OLED component in the prior art;

FIG. 2 schematically shows a structure of an electric-charge connection layer in the prior art;

FIG. 3 schematically shows a structure of an electric-charge connection layer according to an embodiment of the present disclosure;

FIG. 4 schematically shows a flow chart of manufacturing the charge connection layer according to an embodiment of the present disclosure; and

FIG. 5 schematically shows a structure of an electric-charge connection layer according to another embodiment of the present disclosure.

### DETAILED DESCRIPTION OF THE EMBODIMENTS

The present disclosure will be explained in detail below with reference to the embodiments and the accompanying drawings, so that one can fully understand how the present disclosure solves the technical problem and achieves the technical effects, and thereby implements the same. It should be noted that any of the embodiments and any of the technical features thereof may be combined with one another as long as no conflict is caused, and the technical solutions obtained therefrom fall into the scope of the present disclosure.

In the following descriptions, many specific details will be provided for sake of explanation, so that the embodiments of the present disclosure can be completely understood. However, it is obvious for one skilled in the art that the present disclosure may be otherwise not implemented in accordance with these specific details or methods provided herein.

As known in the art, an exciton is a bound state of an electron and a hole; and the more excitons there are, the more photons there will be when the excitons decay, and the higher the efficiency of an OLED component will be. For a traditional OLED component, an exciton formed in a light-emitting zone is a combination of an electron injected from a cathode and a hole injected from an anode, and an injected pair of electron and hole at most can form only one exciton.

However, for a laminated OLED) component, the injected pair of electron and hole can be respectively combined with a hole and an electron generated by an electric-charge connection layer to form two excitons. Therefore, with the increase of the number of light-emitting units, the luminance and efficiency of the laminated OLED component can be doubled, and in the meantime, a voltage of the laminated OLED component can also be increased.

When supplied with a same current density, the laminated OLED component and the traditional OLED component have the same ageing property. However, since the laminated OLED component has a higher initial brightness than the traditional OLED component, when it is configured with the same initial brightness as the traditional one, the laminated OLED component may have a longer lifespan than the traditional OLED component.

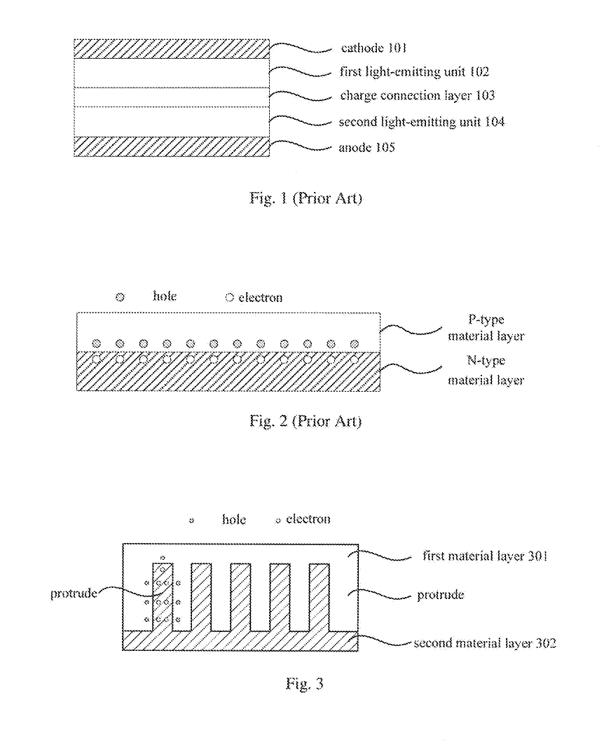

FIG. 1 schematically shows a structure of an existing laminated OLED component.

As shown in FIG. 1, the existing laminated OLED component comprises a cathode 101, a first light-emitting unit 102, a charge connection layer 103, a second light-emitting unit 104, and an anode 105. The cathode 101 is connected to the first light-emitting unit 102. The anode 105 is connected to the second light-emitting unit 104. The charge connection layer 103 is connected between the first light-emitting unit 102 and the second light-emitting unit 104.

FIG. 2 schematically shows a structure of the existing charge connection layer. As shown in FIG. 2, the existing charge connection layer adopts a planar heterojunction structure, and mainly consists of a P-type material layer and an N-type material layer which both adopt a planar construction.

In the laminated OLED component, the charge connection layer serves to connect each of the light-emitting units, and more importantly, it serves to generate carriers and quickly transmit and inject the carriers into the light-emitting units. Thus, the charge connection layer is used to efficiently generate carriers, quickly transmit the carriers, and effectively inject the carriers, wherein efficient generation of carriers by the charge connection layer is the key to obtain a high-performance laminated OLED component.

Since the carriers are generated at a contact region of P/N-type structures, the area of the contact region of the P/N structures determines how many the carriers may be generated. With all conditions being the same, the larger the contact region is, the more carriers the P/N structures can generate; and the smaller the contact region is, the fewer carriers the P/N structures generates.

It can be known from the above description that a focus of the present application to improve the performance of the charge connection layer is how to increase the area of the contact region of the P/N structures. For this reason, the present embodiment provides a charge connection layer as shown in FIG. 3.

As is illustrated in FIG. 3, the charge connection layer provided by the present embodiment comprises a first material layer 301 and a second material layer 302 which both have protrudes formed therein. The first material layer 301 and the second material layer 302 are further provided therein with recessions relative to the protrudes. Each protrude of the first material layer 301 extends into a corresponding recession of the second material layer 302, and each protrude of the second material layer 302 extends into a corresponding recession of the first material layer 301. Thus, in the present embodiment, the first material layer 301 and the second material layer 302 are fitted together with comb-like structures, as shown in FIG. 3.

In order to achieve a close adhesion between the charge connection layer and other material layers (e.g., a light-emitting layer) in the laminated OLED component, as shown in FIG. 3, in the charge connection layer provided by the present embodiment, the protrudes and the recessions of the first material layer 301 are formed on a first side of the first material layer 301, and a second side of the first material layer 301 is flat. The protrudes and the recessions of the second material layer 302 are formed on a second side of the second material layer, and a first side of the second material layer 302 is flat.

In order to improve a speed of injecting the electric-charges and a capability of transmitting the charges, and to reduce voltage drops on an injection layer and a transmission layer in the charge connection layer, the charge connection layer usually adopts a configuration having electrical doping, whereby the luminous efficiency of the laminated OLED component can be improved and the drive voltage thereof can be reduced.

In the present embodiment, the charge connection layer uses P-type dopant and N-type dopant, by means of which the electrical properties of the charge connection layer can be improved. Specifically, the first material layer 301 is a P-type material layer, and the second material layer 302 is an N-type material layer. In the present embodiment, the P-type dopant in the first material layer is F₄-TCNQ:m-MTDATA, and the N-type dopant in the second material layer is Rb₂CO₃.

It should be noted that in other embodiments of the present disclosure, the dopant in the first and/or second material layer can also be other suitable materials, and the present disclosure is not limited thereto. For instance, in other embodiments of the present disclosure, the P-type dopant in the first material layer can be selected from any one or combinations of HAT-CN, FeCl₃:NPB, and MoO₃:NPB. The N-type dopant in the second material layer can be selected from any one or combinations of Li, Mg, Ca, Cs, LiF, CsF, Cs₂CO₃, and CsN₃.

It should also be noted that in the charge connection layer provided by other embodiments of the present disclosure, the first material may be an N-type material layer and the second material layer may be a P-type material layer. The present disclosure is not limited thereto.

For charge connection layers having a same appearance and size (same width in FIG. 3), the area of a contact region of the P/N-type structures (i.e., the area of the contact region of the first material layer 301 and the second material layer 302) in the charge connection layer provided by the present embodiment is considerably larger than that of a contact region of the P/N structures in an existing charge connection layer. Therefore, compared with the existing charge connection layer, the charge connection layer provided by the present disclosure is able to generate more carriers, whereby the performance of the charge connection layer can be improved

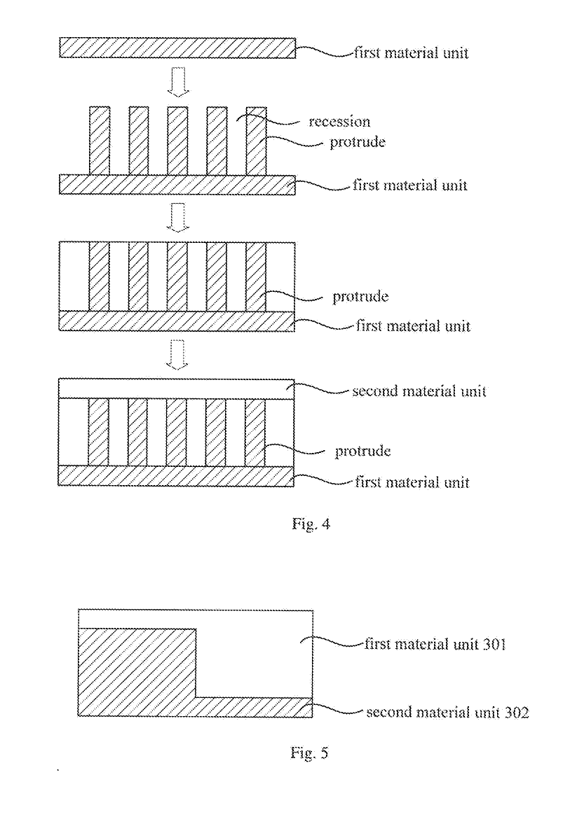

The present disclosure further provides a method for manufacturing the foregoing laminated OLED component. FIG. 4 shows a flow chart of the method.

As shown in FIG. 4, the method for manufacturing the charge connection layer provided by the present embodiment comprises the following steps. First, a first material unit is formed from a first material, and a plurality of protrudes and a plurality of recessions are formed on the first material unit using the first material. Then, each of the recessions is filled with a second material, and a second material unit is formed, using the second material, over the protrudes and the filled recessions. After the above steps, a charge connection layer is obtained. In other embodiments of the present disclosure, the protrudes and the recessions can also be formed by etching. The present disclosure is not limited in this regard.

It should be noted that in the embodiments of the present disclosure, the first material may be a P-type material layer and the second material layer may be an N-type material layer, or the first material may be an N-type material layer and the second material layer may be a P-type material layer. The present disclosure is not limited in this regard.

It should also be noted that in the embodiments of the present disclosure, the protrudes may have a same height or different heights, and the present disclosure is not limited thereto. It is only required that in these charge connection layers, a side of the later formed second material layer, which is arranged to be in contact with other material layers (e.g., a light-emitting unit) of the laminated OLED component, is flat.

Further, it should be noted that in other embodiments of the present disclosure, the first material layer 301 and the second material 302 in the charge connection layer can also adopt other suitable structures and can be fitted together in other suitable ways, and the present disclosure is not limited thereto. For example, in one embodiment of the present disclosure, the charge connection layer adopts a structure as shown in FIG. 5 to increase the area of the contact region of the first material layer and the second material layer, so that the capability of generating carriers is improved.

The present embodiment further provides a laminated OLED component which uses the foregoing charge connection layer. A first light-emitting unit and a second light-emitting unit in the laminated OLED component are connected in series through the charge connection layer. In other embodiments of the present disclosure, there can be more than three light-emitting units in the laminated OLED component, and these light-emitting units can be connected in series through a plurality of charge connection layers as mentioned.

It should be understood that the embodiments disclosed herein are not limited by the specific structures, treatment steps or materials disclosed herein, but incorporate the equivalent substitutes of these features which are comprehensible to those skilled in the art. It should also be noted that the technical terms used herein are used only for describing the specific embodiments, not for limiting them.

As used herein, an “embodiment” means that the specific features, structures and characteristics described in combination with the embodiments are contained in at least one embodiment of the present disclosure. Therefore, the “embodiment” appeared in all parts of the whole description does not necessarily refer to the same embodiment.

For sake of convenience, a plurality of items, structural units, component units and/or materials used herein can be listed in a common list. However, the list shall be understood in a way that each element thereof represents an only and unique member. Therefore, when there is no other explanation, none of members of the list can be understood as an actual equivalent of other members in the same list only based on the fact that they appear in the same list. In addition, the embodiments and examples of the present disclosure can be explained with reference to the substitutes of each of the components. It should be understood that, the embodiments, examples and substitutes herein shall not be interpreted as the equivalents of one another, but shall be considered as separate and independent representatives of the present disclosure.

Furthermore, the features, structures, or properties described herein can be combined with one or more embodiments in any other suitable ways. The details described herein, such as quantity, are for a comprehensive understanding of the embodiments of the present disclosure. However, one skilled in the art should understand that the present disclosure can be implemented without any of the above details, and can be implemented using other methods, components, materials, etc. For clearly showing all aspects of the present disclosure, known structures, materials, or operations are not shown or described in detail in other examples.

The embodiments are described hereinabove to interpret the principles of the present disclosure in one application or a plurality of applications. However, one skilled in the art, without departing from the principles and thoughts of the present disclosure, can make various modifications to the forms, usages and details of the embodiments of the present disclosure without any creative work. The protection scope of the present disclosure shall be determined by the claims.

1. A charge connection layer, comprising a first material layer and a second material layer which are both provided therein with protrudes and recessions,
wherein each protrude of the first material layer extends into a corresponding recession of the second material layer, and each protrude of the second material layer extends into a corresponding recession of the first material layer.

2. The charge connection layer according to claim 1, wherein the first material layer and the second material layer form comb-like structures which are fitted together.

3. The charge connection layer according to claim 1,
wherein the first material layer is a P-type material layer, and the second material layer is an N-type material layer, or
the first material layer is an N-type material layer, and the second material layer is P-type material layer.

4. The charge connection layer according to claim 3, wherein P-type dopant in the P-type material layer is selected from any one or combinations of the following:
HAT-CN, FeCl₃:NPB, MoO₃:NPB, and F₄-TCNQ:m-MTDATA.

5. The charge connection layer according to claim 3, wherein N-type dopant in the N-type material layer is selected from any one or combinations of the following:
Li, Mg, Ca, Cs, LiF, CsF, Cs₂CO₃, CsN₃, and Rb₂CO₃.

6. The charge connection layer according to claim 1, wherein the protrudes and the recessions of the first material layer are formed on a first side of the first material layer, and a second side of the first material layer is flat.

7. The charge connection layer according to claim 2, wherein the protrudes and the recessions of the first material layer are formed on a first side of the first material layer, and a second side of the first material layer is flat.

8. The charge connection layer according to claim 3, wherein the protrudes and the recessions of the first material layer are formed on a first side of the first material layer, and a second side of the first material layer is flat.

9. The charge connection layer according to claim 6, wherein the protrudes and the recessions of the second material layer are formed on a second side of the second material layer, and a first side of the second material layer is flat.

10. A laminated OLED component, comprising a first light-emitting unit, a second light-emitting unit, and a charge connection layer, wherein the first light-emitting unit and the second light-emitting unit are connected in serials through the charge connection layer,
wherein the charge connection layer comprises a first material layer and a second material layer which are both provided therein with protrudes and recessions, wherein each protrude of the first material layer extends into a corresponding recession of the second material layer, and each protrude of the second material layer extends into a corresponding recession of the first material layer.

11. The laminated OLED component according to claim 10, wherein the first material layer and the second material layer form comb-like structures which are fitted together.

12. The laminated OLED component according to claim 10,
wherein the first material layer is a P-type material layer, and the second material layer is an N-type material layer, or
the first material layer is an N-type material layer, and the second material layer is P-type material layer.

13. The laminated OLED component according to claim 12, wherein a P-type dopant in the P-type material layer is selected from any one or combinations of the following:
HAT-CN, FeCl₃:NPB, MoO₃:NPB, and F₄-TCNQ:m-MTDATA.

14. The laminated OLED component according to claim 12, wherein N-type dopant in the N-type material layer is selected from any one or combinations of the following:
Li, Mg, Ca, Cs, LiF, CsF, Cs₂CO₃, CsN₃, and Rb₂CO₃.

15. The laminated OLED component according to claim 10, wherein the protrudes and the recessions of the first material layer are formed on a first side of the first material layer, and a second side of the first material layer is flat.

16. The laminated OLED component according to claim 11, wherein the protrudes and the recessions of the first material layer are formed on a first side of the first material layer, and a second side of the first material layer is flat.

17. The laminated OLED component according to claim 12, wherein the protrudes and the recessions of the first material layer are formed on a first side of the first material layer, and a second side of the first material layer is flat.

18. The laminated OLED component according to claim 15, wherein the protrudes and the recessions of the second material layer are formed on a second side of the second material layer, and a first side of the second material layer is flat.

19. A method for manufacturing a laminated OLED component, comprising:
forming a first material unit from a first material, and forming a plurality of protrudes and a plurality of recessions on the first material unit using the first material, and
filling each of the recessions with a second material, and forming a second material unit over the protrudes and the filled recessions using the second material.

20. The method according to claim 19,
wherein the first material is a P-type material and the second material is an N-type material, or
the first material is an N-type material and the second material is a P-type material.
